(19) United States
(12) Patent Application Publication
(10) Pub. No.: US 2013/0082383 A1
(43) Pub. Date: Apr. 4, 2013

(54) ELECTRONIC ASSEMBLY HAVING MIXED INTERFACE INCLUDING TSV DIE

(71) Applicant: KENGO AOYA, HIJI-MACHI (JP)

(72) Inventor: KENGO AOYA, HIJI-MACHI (JP)

(73) Assignee: TEXAS INSTRUMENTS INCORPORATED, Dallas, TX (US)

(21) Appl. No.: 13/251,544

(22) Filed: Oct. 3, 2011

(51) Int. Cl. H01L 23/498; H01L 21/50

(52) U.S. Cl. 257/738; 438/118; 257/E23.069; 257/E21.499

(57) ABSTRACT

An electronic assembly includes an interposer having an inner aperture including a first side and a second side. A through-substrate-via (TSV) die is within the aperture including a plurality of TSVs, a bottomside, and a topside including topside bonding features thereon including of a first portion of the plurality of TSVs or pads coupled to the first TSVs. A ball grid array (BGA) is coupled to the topside bonding features of the TSV die and to pads on the second side of the interposer. Mold material is over at least a portion of the first side of the interposer, and within the inner aperture to fill a gap between the TSV die and the interposer. Respective ones of a second portion of the plurality of TSVs from the bottomside of the TSV die are connected by a lateral connector to pads on the first side of the interposer.

### FIELD

Disclosed embodiments relate to electronic assemblies including through-substrate-via die and interposers.

### BACKGROUND

A conventional packaging approach for surface mounting a through-silicon-via (TSV) die to a workpiece, such as a printed circuit board (PCB), is to include an interposer between the TSV die and the workpiece. A ball grid array (BGA) can be provided on the side of the interposer opposite the TSV die. Metal layers provided by the interposer can be used for signal redirection to widen the ball pitch of the BGA as compared to the pitch of bonding features on the TSV die coupled to the TSVs to allow for surface mounting to workpieces having standard (larger) ball pitches.

Such conventional packaging approaches have associated problems. Fine pitch TSV bonding features (e.g., solder capped copper pillars coupled to the TSVs) on the active topside of the die need precise mount accuracy to avoid inadvertent shorting to pads on the surface of the workpiece. In addition, heat transfer from the TSV die (and commonly from a top die on the TSV die as well) thereon may be reduced by the thermal conductivity of the interposer, which may be low due to use of a low thermal conductivity interposer material as compared to the thermal conductivity of the substrate for the die, such as silicon. Moreover, the interposer can add significant height to the electronic assembly.

Embedded Wafer Level BGA (eWLB) can be used as an alternative to the conventional approach described above. In eWLB a redistribution layer (RDL) including RDL pads is formed over both the topside of the TSV die and mold material lateral to the TSV die that enables a BGA to be formed on the RDL pads (which are wider pitched as compared to the bonding feature pitch on the TSV die). However, problems with eWLB include requiring wafer level molding which is difficult to control the warpage, and difficulties forming an RDL over an interface including both mold material and the TSV die substrate, such as silicon.

### SUMMARY

Disclosed embodiments include electronic assemblies comprising through-substrate-via (TSV) die and an interposer that are configured as a single layer for mounting on a workpiece. Such electronic assemblies avoid the need for a conventional interposer under the TSV die. Some TSVs on the TSV die that referred herein as “second TSVs” couple through the die via lateral connectors on the bottomside of the TSV die which provide rerouting so that some connections to the TSV die are accessed lateral to the area of the TSV die. Such lateral contacts effectively expand the area of the TSV die so a workpiece (e.g., PCB) having bonding features that span an area greater than the area of the TSV die (and generally a wider bonding pitch) may be directly surface mounted thereto.

Disclosed interposers include an inner aperture that allows the TSV die to be assembled with its active topside down within the inner aperture. Rerouting of some of the connections to the TSV die is provided by lateral connectors (e.g., bond wires, or a bottomside redistribution layer (RDL)) that provides connection between the second TSVs from the bottomside of the TSV die to the interposer. A RDL may also be included on the topside of the TSV die to reposition contacts to TSVs other than the second TSVs (“first TSVs”) on the topside of the TSV die. Following molding, the TSV die/interposer combination forms a reconstituted single layer TSV die/interposer. A BGA can be directly attached to the single layer TSV die/interposer. The BGA balls on the TSV die provides direct coupling to the first TSVs and the BGA balls on the interposer provide coupling through the interposer and lateral connectors (e.g., bond wires) to the second TSVs. The BGA can have an area larger than the area of the TSV die, which enables electronic assemblies to provide a desired wider pitch compared to the TSV pitch on the TSV die.

### BRIEF DESCRIPTION OF THE DRAWINGS

FIG. 1A is a cross sectional depiction of an example electronic assembly including a TSV die and an interposer configured as a single layer, according to an example embodiment.

FIG. 1B is a bottom view depiction of the electronic assembly shown in FIG. 1A.

FIG. 2 is a flow chart that shows steps in an example method for forming an electronic assembly including a TSV die and an interposer configured as a single layer, according to an example embodiment.

FIG. 3A is a cross sectional depiction of an example electronic assembly including a TSV die and an interposer configured as a single layer, where the TSV die is a dual-sided RDL die, according to an example embodiment.

FIG. 3B is a cross sectional depiction of an example electronic assembly including a TSV die and an interposer configured as a single layer including a through mold via (TMV) type connection, according to an example embodiment.

FIG. 3C is a cross sectional depiction of an example electronic assembly including a TSV die and an interposer configured as a single layer including a package on package (PoP) type arrangement, according to an example embodiment.

FIG. 3D is a cross sectional depiction of an example electronic assembly including a TSV die and an interposer configured as a single layer including a mold surface RDL type arrangement, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

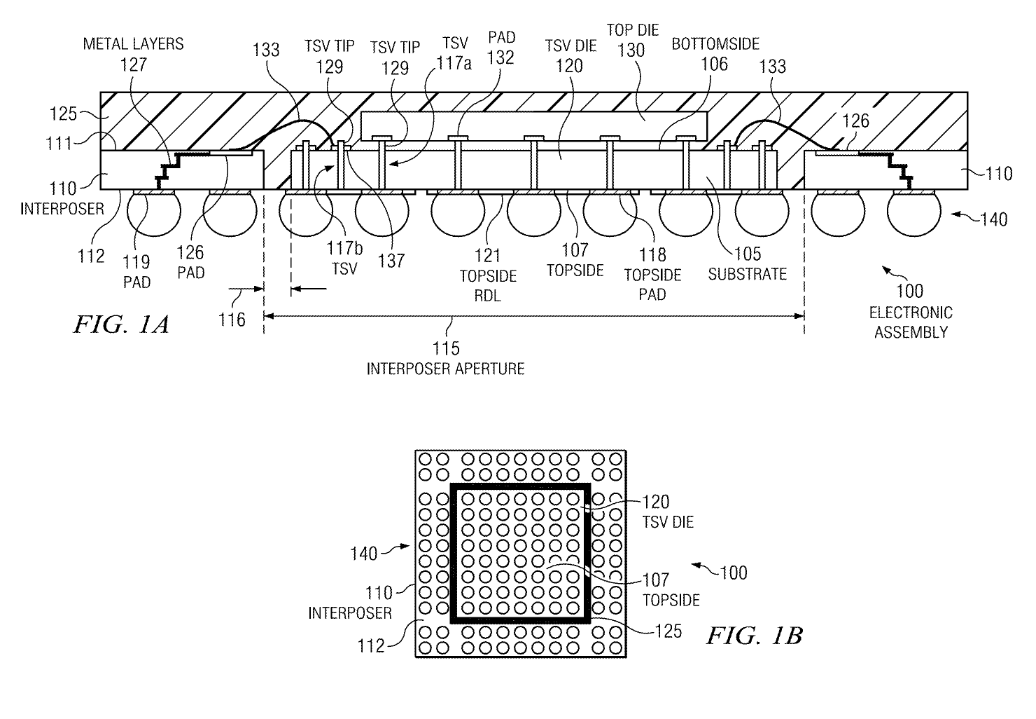

FIG. 1A is a cross sectional depiction of an example electronic assembly 100 including a TSV die 120 and an interposer 110 configured as a single layer, according to an example embodiment. FIG. 1 B is a bottom view depiction of the electronic assembly 100 shown in FIG. 1A. Interposer 110 includes an inner aperture 115 shown in FIG. 1A as an “interposer aperture” 115. The TSV die 120 is positioned within the inner aperture 115.

The interposer 110 can comprise various materials such as silicon, ceramic materials, or organic (e.g., polymer) materials, and can include multiple metal layers, such as a wire bond layer, one or more redistribution layers, and a ground layer. Various methods can be used to form the inner apertures 115 in the interposer 110, including a mechanical router to form a plurality of apertures in an interposer sheet or panel comprising a plurality of interposers. The dimensions and shape of the inner aperture 115 can be based on the dimensions and shape of the semiconductor die or die stack to be positioned within.

The interposer 110 includes a first side 111 and a second side 112. Pads 126 are on the first side 111, and pads 119 are on the second side 112. Some of the pads 126 are shown connected by the metal layers 127 within the interposer 110 to respective ones of the pads 119.

TSV die 120 comprises a substrate 105, and includes a plurality of TSVs collectively referred to as TSVs 117, with a first portion of the TSVs shown as first TSVs 117a and a second portion of the TSVs shown as second TSVs 117b. The TSVs 117 can comprise an outer dielectric liner and an inner metal core. For inner metal core metal materials such as copper, the TSVs also generally include a diffusion barrier layer, such as a refractory metal or a refractory metal nitride, between the dielectric liner and the inner metal core. In the case the substrate 105 comprises a silicon substrate, the TSVs 117 comprise through-silicon-vias.

The TSVs 117 are shown in FIG. 1A including optional protruding TSV tips 129. In one embodiment protruding TSV tips 129 may protrude a distance of about 5 μm to 15 μm from the bottomside 106 of the substrate 105. Each TSV 117b is shown including a TSV wire bond pad 137 coupled thereto. Wire bond pads 137 are shown coupled to wire bond pads 137.

However, in another embodiment, the TSVs 117 do not protrude from the bottomside 106 of the substrate 105. In this embodiment the TSV die 120 can include an RDL on the bottomside 106 that provides TSV wire bond pads coupled to the TSVs 117. Bond wires can also be coupled directly to the top of the TSV itself on the bottomside 106 of the TSV die 120. To facilitate wire bonding to the tops of the TSVs, TSVs 117 may be larger in area as compared to the minimum TSV area otherwise possible, such as at least 40 μm diameter for current technology. In one particular embodiment the inner metal core of the TSVs 117 comprises copper, the dielectric liner comprises silicon oxide, and the diffusion barrier layer comprises TaN.

The TSV die 120 includes a topside 107 including active circuitry (not shown), and topside bonding features shown as topside pads 118 connected respective ones of the first TSVs 117a by the topside RDL 121 shown in FIG. 1A. The second TSVs 117b are not connected to topside pads 118, and are thus not connected to balls of the BGA 140. Second TSVs 117b are instead coupled through the substrate 105 of the TSV die 120 via a lateral coupler to the interposer 110, with the lateral couplers shown in FIG. 1A provided by bond wires 133. Although not shown in FIG. 1A, in one embodiment the topside bonding features can comprise direct connections to the first TSVs 117a (i.e., no RDL).

Mold material 125 is over the first side 111 of the interposer 110, and is within the inner aperture 115 to fill a gap 116 between the TSV die 120 and the interposer 110. Respective second TSVs 117b from the bottomside 106 of the TSV die 120 are shown connected to the pads 126 on the first side 111 of the interposer 110 by the bond wires 133.

Supported by the mold material 125, the TSV die/interposer combination provides a reconstituted single layer TSV die 120/interposer 110. The BGA 140 comprising a plurality of BGA balls is on the mixed interface provided by TSV die 120/interposer 110. The BGA balls on the TSV die 120 provide direct coupling to the first TSVs 117a and the BGA balls on the interposer 110 provide coupling through the interposer 110 and the bond wires 133 shown act as lateral connectors to the second TSVs 117b. An optional top die (e.g., a memory die) 130 having pads 132 is shown joined to the TSV tips 129 of the first TSVs 117a on the bottomside 106 of the TSV die 120.

The TSV die 120 can be designed so that first TSVs 117a are used for higher speed pins on the TSV die 120 to improve transient performance. For example, in one embodiment, the TSV die 120 is designed so that the first TSVs 117a couple to relatively high speed signal I/O pins on the TSV die 120 to provide direct ball attach (with associated lower parasitics), while second TSVs 117b can couple to relatively low speed signal I/O as well as power supply and ground pins, that laterally connect to the interposer 110 by the bond wires 133 shown in FIG. 1A (with associated higher parasitics).

Disclosed electronic assemblies, such as the electronic assembly 100 shown in FIGS. 1A and B, provide several significant advantages as compared to conventional TSV package arrangements that position the interposer under the TSV die. Disclosed electronic assemblies provide a thinner package as compared to such conventional TSV package arrangements. Removal of the interposer from under the TSV die also improves heat transfer efficiency to an underlying workpiece as compared to conventional package arrangements where the series interposer adds thermal resistance and thus reduces heat transfer to an underlying workpiece. In addition, since disclosed embodiments remove the interposer from under the TSV die, the interposer material can be selected without regard its thermal conductivity, which enables the use of relatively low cost organic (e.g., polyimide) interposers (low cost as compared to the cost of glass or silicon interposers), without degrading heat transfer to the workpiece. Moreover, disclosed electronic assemblies can remove the fine pitch die mount needs for TSV die that result in severe mount accuracy needed for conventional TSV package arrangements where the interposer is under the TSV die.

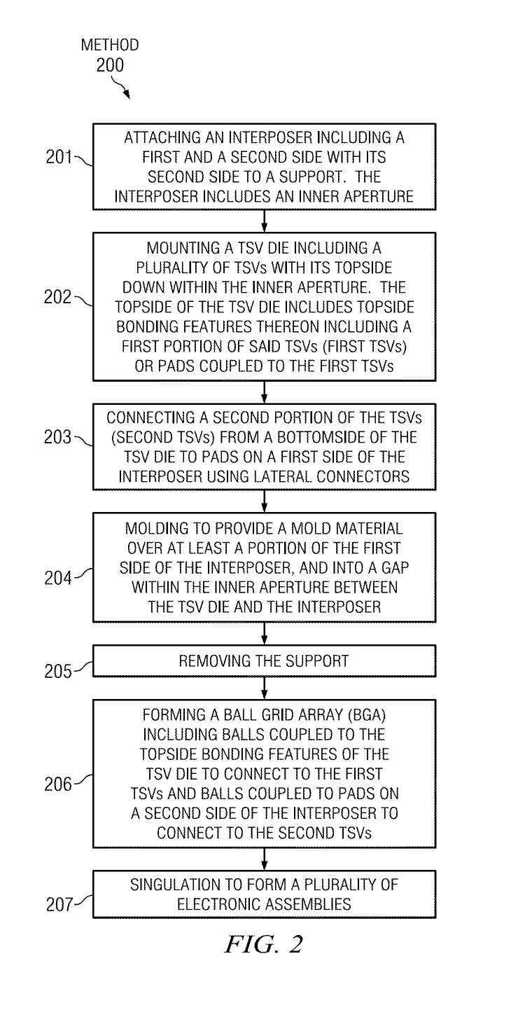

FIG. 2 is a flow chart that shows steps in an example method 200 for forming an electronic assembly including a TSV die and an interposer configured as a single layer, such as the electronic assembly 100 shown in FIGS. 1A and 1B, according to an example embodiment. Step 201 comprises attaching an interposer 110, typically an interposer panel/sheet comprising a plurality of interposers 110, with each interposer having an inner aperture 115, including a first side 111 and a second side 112, with the second side 112 being attached to a support. The support can comprise a support tape or a carrier (e.g. silicon or quartz carrier). A suitable adhesive can be used for the attachment. In one particular embodiment, the support tape can be a tape that is commonly used for leadframe substrates to prevent mold flashing.

Step 202 comprises mounting a TSV die 120 including a plurality of TSVs 117 including a bottomside 106 and a topside 107 with its topside down within the inner aperture 115. The topside 107 includes active circuitry and topside bonding features. The topside bonding features comprise the first TSVs 117a or topside pads 118 coupled to first TSVs 117a. A die stack comprising a top die 130 (or die stack) bonded to the TSV die 120 can be mounted in step 202. Top die mounting can comprise die-to-die or die-to-wafer mounting. In the die-to-TSV wafer case there will be a singulation step to form stacked die before mounting the stacked die in the aperture 115 of the interposer 110.

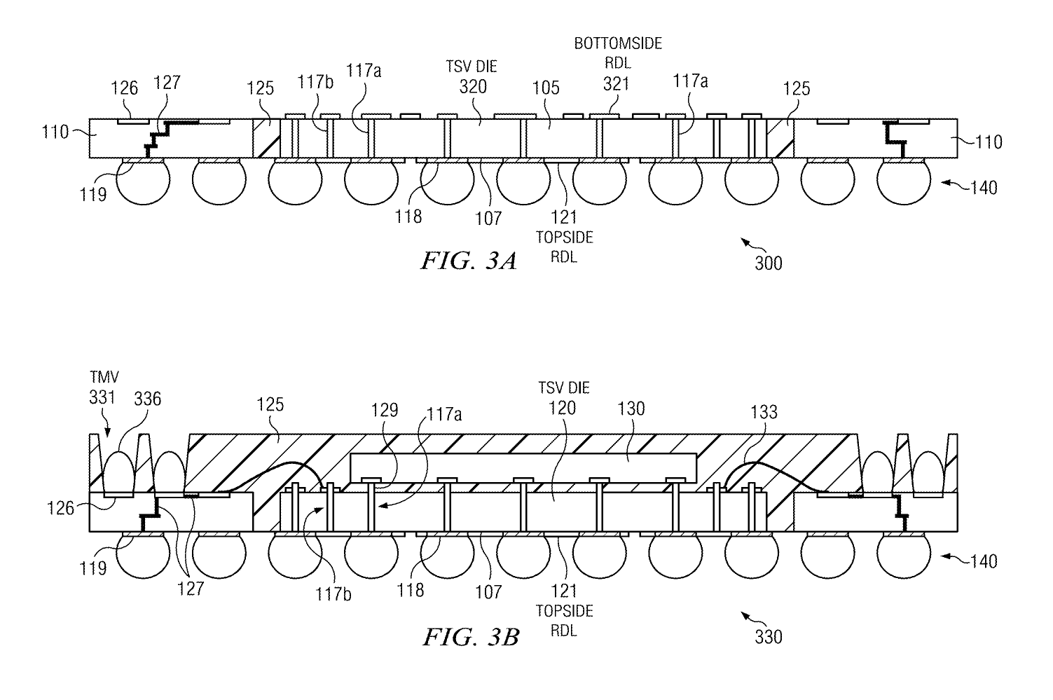

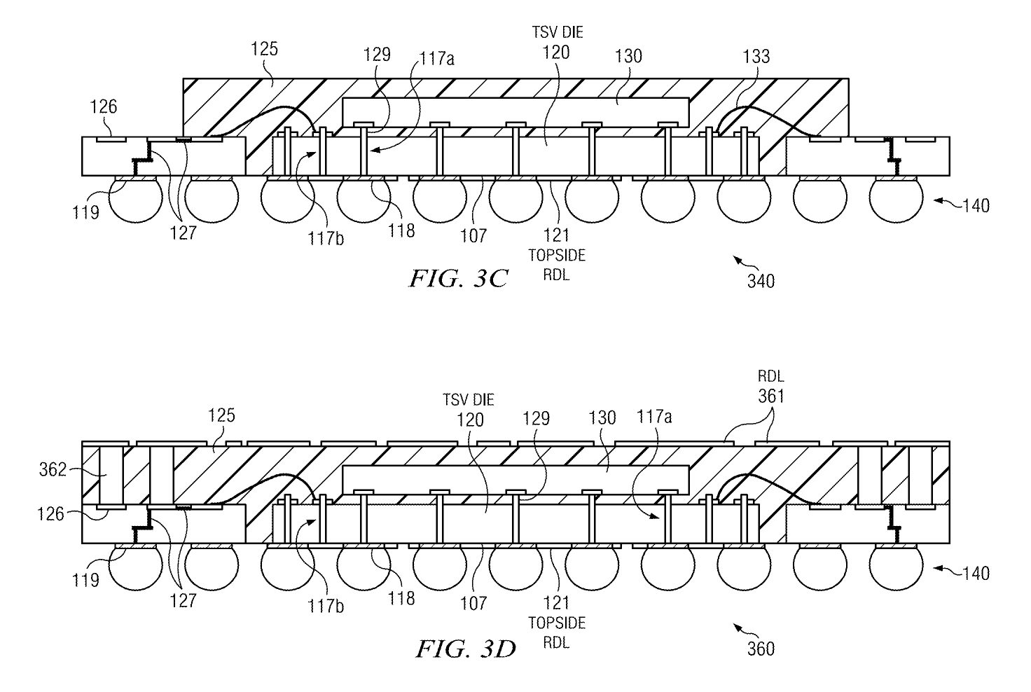

Step 203 comprises connecting the second TSVs 117b from the bottomside 106 of the TSV die 120 to pads on the first side 111 of the interposer 110 using lateral connectors. In one embodiment bond wires 133 are used as the lateral connectors. An alternative to bond wires is provided by a TSV die having a dual-sided RDL structure described below (see FIG. 3A described below). Yet another alternative is a stacked package (e.g., a memory package) that provides the routing for the connection between the second TSVs 117b and the interposer 110. (see FIG. 3C described below).

Step 204 comprises molding to provide a mold material 125 over at least a portion of the first side 111 of the interposer 110, including into a gap 116 within the inner aperture 115 between the TSV die 120 and the interposer 110. Supported by the mold material 125 the TSV die/interposer combination provides a reconstituted single layer TSV die/ interposer. Step 205 comprises removing the support, such as a support tape or a carrier wafer. Step 206 comprises forming a BGA including balls coupled to the topside bonding features of the TSV die 120 and balls coupled to pads 119 on the second side 112 of the interposer 110. The BGA balls on the TSV die 120 provide direct coupling to the first TSVs 117a and the BGA balls on the interposer 110 provide coupling through the interposer and a lateral connector to the second TSVs 117b. Step 207 comprises singulation to form a plurality of electronic assemblies.

Disclosed embodiments can include numerous connection options for connecting TSVs using contacts on the bottomside of the TSV die to the interposer, and optionally from the interposer to another device. For example, FIG. 3A is a cross sectional depiction of an example electronic assembly 300 including a TSV die 320 and an interposer 110 configured as a single layer, according to an example embodiment. The TSV die 320 has a dual-sided RDL including topside RDL 121 and bottomside RDL 321. The TSVs 117a and 117b are shown as flat/planar TSVs that do not protrude from the bottomside 106 of the substrate 105. In this embodiment a top package (e.g., a memory package; not shown) can provide the routing from the second TSVs 117b to pads provided by bottomside RDL 321 for the connection between the second TSVs 117b and pads 126 on the interposer 110.

FIG. 3B is a cross sectional depiction of an example electronic assembly 330 including a TSV die 120 and an interposer 110 configured as a single layer, where the electronic assembly 330 includes a TMV type connection, according to an example embodiment. In this embodiment, as in FIGS. 1A and 1B, bond wires 133 provide lateral coupling between the second TSVs 117b and pads 126 on interposer 110. TMVs 331 allow balls 336 to be positioned on pads 126 which provides the opportunity to couple to nodes of a top die (or die stack) or top package to the second TSVs 117b.

FIG. 3C is a cross sectional depiction of an example electronic assembly 340 including a TSV die 120 and an interposer 110 configured as a single layer, where the electronic assembly includes a PoP type arrangement, according to an example embodiment. In this embodiment the mold material 125 covers only a portion of the first side of the interposer 110, which allows for a package to connect to pads 126 on the first side 111 of the interposer 110 for connection to second TSVs 117b. Thus, as with electronic assembly 330 shown in FIG. 3B, electronic assembly 340 provides the opportunity to couple the nodes of a top package to the second TSVs 117b.

Selective mold material 125 can be formed using processes including liquid mold or transfer mold with top gate type processes. For liquid mold processing, liquid mold is dispensed on the top die 130. A mold die can provide substrate clamping. For transfer mold processing, a mold die clamps the substrate, and mold compound can be then injected through top gate on the mold die.

FIG. 3D is a cross sectional depiction of an example electronic assembly 360 including a TSV die 120 and an interposer 110 configured as a single layer, where the electronic assembly includes a mold surface RDL type arrangement, according to an example embodiment. In this embodiment vias are formed in the mold material 125 over pads 126, followed by metallization to form metal filled vias 362 and an RDL 361 coupled to the metal filled vias 362 on the top surface of the mold material 125.

Disclosed embodiments can be integrated into a variety of assembly flows to form a variety of different semiconductor integrated circuit (IC) devices and related products. The assembly can comprise single semiconductor die or multiple semiconductor die, such as PoP configurations comprising a plurality of stacked semiconductor die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

I claim:

1. An electronic assembly:
an interposer having an inner aperture including a first side and a second side;
a through-substrate-via (TSV) die within said aperture including a substrate and a plurality of TSVs, a bottomside, and a topside including topside bonding features thereon including a first portion of said plurality of TSVs (first TSV) or topside pads coupled to said first TSVs;
a ball grid array (BGA) coupled to said topside bonding features of said TSV die and to pads on said second side of said interposer, and
mold material over at least a portion of said first side of said interposer, and within said inner aperture that fills a gap between said TSV die and said interposer,
wherein respective ones of a second portion of said plurality of TSVs (second TSVs) from said bottomside of said TSV die are connected by a lateral connector to pads on said first side of said interposer.

2. The electronic assembly of claim 1, wherein said substrate comprises silicon, wherein said plurality of TSVs comprise through-silicon-vias, and wherein said interposer comprises an organic interposer.

3. The electronic assembly of claim 1, wherein said topside bonding features comprise said topside pads, further comprising a topside redistribution layer (RDL) on said topside, wherein said topside pads are coupled to said topside RDL.

4. The electronic assembly of claim 1, further comprising a top package bonded to said first TSVs.

5. The electronic assembly of claim 4, wherein said first TSVs include TSV tips that protrude from said bottomside, and wherein said top package is bonded to said TSV tips.

6. The electronic assembly of claim 1, wherein said lateral connectors comprise bond wires for coupling respective ones of said second TSVs from said bottomside of said TSV die to said pads on said first side of said interposer.

7. The electronic assembly of claim 1, wherein said topside bonding features comprise said topside pads, further comprising:
a topside redistribution layer (RDL) on said topside, wherein said topside pads are coupled to said topside RDL, and
a bottomside RDL on said bottomside of said TSV die, wherein said bottomside RDL is coupled to said second TSVs.

8. The electronic assembly of claim 1, wherein said electronic assembly provides contact to a portion of said pads on said first side of said interposer.

9. The electronic assembly of claim 8, wherein said contact to said portion of said pads on said first side of said interposer comprises metal filled through mold via (TMV) contacts formed through said mold material.

10. The electronic assembly of claim 8, wherein said mold material only covers a portion of said first side of said interposer to provide said contact to said portion of said pads on said first side of said interposer.

11. The electronic assembly of claim 8, further comprising metal filled vias formed in said mold material to provide said contact to said portion of said pads on said first side of said interposer, and an RDL coupled to said metal filled vias on a top surface of said mold material.

12. A method for forming an electronic assembly, comprising:
attaching an interposer having an inner aperture including a first side and a second side with said second side onto a support;
mounting a through-substrate-via (TSV) within said inner aperture that includes a substrate, a bottomside, and a topside with said topside down onto said support, wherein said topside includes topside bonding features thereon including a first portion of said TSVs (first TSVs) or pads coupled to said first TSVs;
connecting a second portion of said TSVs (second TSVs) to pads on said first side of said interposer;
molding a mold material over at least a portion of said first side of said interposer, and into a gap within said inner aperture between said TSV die and said interposer;
removing said support, and
forming a ball grid array (BGA) coupled to said topside bonding features of said TSV die and pads on said second side of said interposer.

13. The method of claim 12, wherein said connecting comprises wire bonding to form bond wires for coupling respective ones of said second TSVs from said bottomside of said TSV die to said pads on said first side of said interposer.

14. The method of claim 12, wherein said topside bonding features comprise said topside pads, further comprising forming a topside redistribution layer (RDL) on said topside, wherein said topside pads are coupled to said topside RDL.

15. The method of claim 12, further comprising bonding a top package onto said TSV die to provide contact to said first TSVs.

16. The method of claim 15, wherein said first TSVs include TSV tips that protrude from said bottomside, and wherein said top package is bonded to said TSV tips.

17. The method of claim 12, wherein said topside bonding features comprise said topside pads, further comprising:
forming a topside redistribution layer (RDL) on said topside, wherein said topside pads are coupled to said topside RDL, and
forming a bottomside RDL on said bottomside of said TSV die, wherein said bottomside RDL is coupled to said second TSVs.

18. The method of claim 12, wherein said electronic assembly includes contact to a portion of said pads on said first side of said interposer, further comprising forming metal filled through mold via (TMV) contacts to provide said contact to said portion of said pads on said first side of said interposer.

19. The method of claim 12, wherein said electronic assembly includes contact to a portion of said pads on said first side of said interposer, and wherein said molding comprises a mold process that selectively positions said mold material only over a portion of said first side of said interposer to allow said contact to said portion of said pads on said first side of said interposer.

20. The method of claim 12, wherein said electronic assembly includes contact to a portion of said pads on said first side of said interposer, further comprising:
forming metal filled vias in said mold material to provide said contact to said portion of said pads on said first side of said interposer, and
forming an RDL coupled to the metal filled vias on a top surface of said mold material.

21. The method of claim 12, wherein said substrate comprises silicon, wherein said plurality of TSVs comprise through-silicon-vias, and wherein said interposer comprises an organic interposer.
